(19) United States
(12) Patent Application Publication
(10) Pub. No.: US 2011/0278435 A1
(43) Pub. Date: Nov. 17, 2011

(54) IMAGE SENSOR APPARATUS

(75) Inventor: Yoshiyuki Okuda, Kofu-shi (JP)

(73) Assignee: PIONEER CORPORATION, Kawasaki-shi, Kanagawa (JP)

(21) Appl. No.: 13/143,786

(22) PCT Filed: Jan. 9, 2009
(86) PCT No.: PCT/JP2009/050231

§ 371 Date: Aug. 8, 2011

(51) Int. Cl. H01L 27/146

(52) U.S. Cl. 250/208.1

(57) ABSTRACT

An image sensor comprises a photoelectric-conversion-film current detector which detects a photoelectric conversion film current produced by combination of holes generated in a photoelectric conversion film with electrons supplied from an electron supplying source array to the photoelectric conversion film; a plurality of integrators which sequentially perform temporal integration on the photoelectric conversion film current during respective corresponding pixel periods during which electrons are supplied to said pixel areas, so as to generate integral signals; and sampling means which samples the integral signals of the plurality of integrators in each of the pixel periods to generate an image signal.

### TECHNICAL FIELD

The present invention relates to an image sensor apparatus which comprises an image sensing device that has an electron supplying source array having electron supplying sources arranged therein and a photoelectric conversion film, and a drive circuit for driving the image sensing device.

### BACKGROUND ART

There has been proposed an image sensor apparatus which comprises an electron emission source array wherein electron emission sources from which electrons are pulled out by applying an electric field are arranged in a matrix, and a photoelectric conversion film (e.g., Patent Document 1, as in the following). Among cold cathode electron emission sources, there are, for example, a HEED (high-efficiency electron emission device) (e.g., Non-Patent Document 1, as in the following) and a spint-type cold cathode array as well as a carbon-nanotube-type one. Since the HEED has advantages that it can be driven with a low voltage and that its structure is simple, the research of application to image sensing devices is being conducted. Among other electron supplying element arrays, there is a switching transistor array comprising switching transistors wherein collector or drain electrodes are connected to the pixel areas of a photoelectric conversion film.

An example of the photoelectric conversion film is a HARP (High-gain Avalanche Rushing amorphous Photoconductor) photoelectric conversion film.

For example, in an image sensor apparatus using a cold cathode electron emission element array, each of the cold cathode electron emission elements performs electron beam emission (electron beam irradiation) to a corresponding pixel area of the photoelectric conversion film during its drive period. Thereby, a corresponding amount of positive holes to the incident light amount accumulated in the pixel area of the photoelectric conversion film are neutralized, and the neutralization current is drawn out via the electrode of the photoelectric conversion film so that the image signal for that pixel area of the photoelectric conversion film is detected. Note that in a switching transistor array, the image signal is detected using current injection into the photoelectric conversion film instead of the electron beam irradiation.

The conventional-art apparatus is configured such that, for example, as shown in FIG. 1, the neutralization current (HARP current) is drawn out by a photoelectric-conversion-film current detector 101 via the electrode (HARP electrode) of the photoelectric conversion film and is converted to a voltage value to pass through a low-pass filter (LPF) 102 so that an image signal component is extracted. The biggest advantage of this method is that the circuit is simple.

Where there is variation in the amount of emitted electrons (HEED emission current) between pixels PX(j), PX(j+1) as shown in FIG. 2, for the pixel PX(j) with a smaller amount of emitted electrons, the wave height is lower and the duration T(j) is longer, and for the pixel PX(j+1) with a larger amount of emitted electrons, the wave height is higher and the duration T(j+1) is shorter. Because the HARP current integral value Ih(k)×T(k)=Qₚₓ(k), where k=j, j+1, represents the amount of accumulated holes in the corresponding pixel of the photoelectric conversion film, its DC (direct current) component after passing through the LPF 102 is the image signal for that pixel, although the amount of emitted electrons varies for each electron emission element.

However, where there is variation in the amount of emitted electrons between the electron emission elements as shown in FIG. 2, because the pulse width and height of the photoelectric conversion film (HARP) current waveform are different for each electron emission element, the waveform after passing through the LPF 102 is in an irregularly modulated state. That is, frequency components due to the irregular modulation occur within the band of the LPF 102 unlike in the case where HARP current pulses are even. Thus, there is the problem that when there is variation in the amount of emitted electrons between the electron emission elements, it is seen as noise in the image signal, resulting in a decrease in signal-to-noise ratio (S/N) and degradation in image quality.

Further, as the demand for higher definition in image sensor apparatuses is growing, it is desired to realize an image sensor apparatus which can operate at high speed and which is of high image quality and high performance with high S/N. Also, it is desired to realize an image sensor apparatus capable of high-speed capturing (or slow motion capturing) where the number of frames per unit time is several or more times the normal one. In this high-speed capturing, above-mentioned noise in the image signal is even greater, resulting in a serious adverse effect thereon. However, to date, a high-speed image sensor apparatus capable of reducing effectively such noise has not been realized.
Patent Document 1: Japanese Patent Application Laid-Open Publication No. H06-176704
Non-Patent Document 1: PIONEER R&D, Vol. 17, No. 2, 2007, pp. 61-69

### DISCLOSURE OF THE INVENTION

### Problem to be Solved by the Invention

The present invention has been made in view of the above facts, and an object thereof is to provide a high-speed image sensor apparatus capable of high image quality capturing with high S/N even at high-speed operation.

### Means for Solving the Problem

According to the present invention, there is provided an image sensor apparatus which includes a photoelectric conversion film generating holes due to light incidence; an electron supplying source array having a plurality of electron supplying sources arranged in a matrix; and a scan driver that scans the electron supplying source array to supply electrons sequentially to a plurality of pixel areas of the photoelectric conversion film. The image sensor apparatus comprises:

a photoelectric-conversion-film current detector which detects a photoelectric conversion film current produced by combination of holes generated in a photoelectric conversion film with electrons supplied from an electron supplying source array to the photoelectric conversion film;

a plurality of integrators which sequentially perform temporal integration on the photoelectric conversion film current during respective corresponding pixel periods during which electrons are supplied to said pixel areas, so as to generate integral signals; and

sampling means which samples the integral signals of the plurality of integrators in each of the pixel periods to generate an image signal.

### BRIEF DESCRIPTION OF DRAWINGS

FIG. 1 is a block diagram showing the related-art configuration where a neutralization current is drawn out via an electrode of a photoelectric conversion film and an image signal component is extracted through a low-pass filter (LPF);

FIG. 2 is a diagram showing noise due to irregular modulation occurs within the band of the LPF in the conventional art shown in FIG. 1 when there is variation in the amount of emitted electrons between electron emission elements;

FIG. 3 is a cross-sectional view schematically showing the configuration of a HEED cold cathode HARP sensing device;

FIG. 4 is a block diagram showing the configuration of a HEED cold cathode array, a Y-scan driver and an X-scan driver for driving the HEED cold cathode array, and a controller for controlling the entire apparatus;

FIG. 5 is a diagram for illustrating the structure of an active drive HEED cold cathode array, which is a partial cross-sectional view showing schematically a pixel portion;

FIG. 6 is a diagram schematically showing the configuration of an image sensor apparatus of Embodiment 1;

FIG. 7 is a block diagram showing the configuration of an image signal detecting unit shown in FIG. 6;

FIG. 8 is a diagram schematically showing the output signal waveform of each constituent of the image signal detecting unit shown in FIG. 7;

FIG. 9 is a diagram schematically showing the operation of a first integrator in the case where the amounts of incident light on the pixel areas of a HARP photoelectric conversion film are the same and where the amounts of emitted electrons from the elements of the HEED cold cathode array are different;

FIG. 10 is a block diagram showing the configuration of the image signal detecting unit that is Embodiment 2 of the present invention;

FIG. 11 is a diagram showing schematically the output signal waveform of each constituent of the image signal detecting unit shown in FIG. 10;

FIG. 12 is a diagram showing schematically the output signal waveform of the image signal detecting unit for the case where normal capturing mode (i.e., single speed) capturing is performed, which is Embodiment 3 of the present invention;

FIG. 13 is a circuit diagram showing an example of the circuit configuration of the integrator;

FIG. 14 is a circuit diagram showing another example of the circuit configuration of the integrator; and

FIG. 15 is a circuit diagram showing another example of the circuit configuration of the integrator.

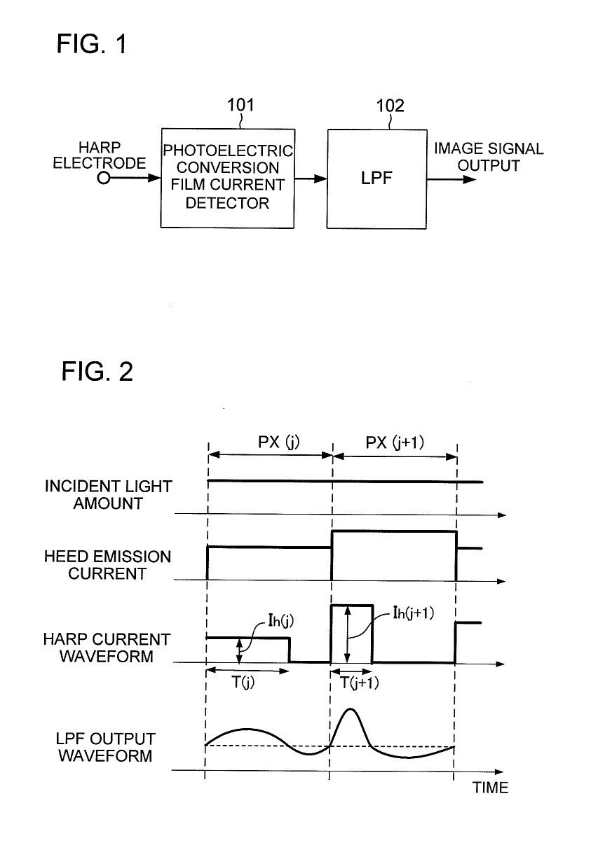

### BEST MODE FOR CARRYING OUT THE INVENTION

Embodiments of the present invention will be described below with reference to the drawings. The same reference numerals are used to denote the same or equivalent constituents.

### Embodiment 1

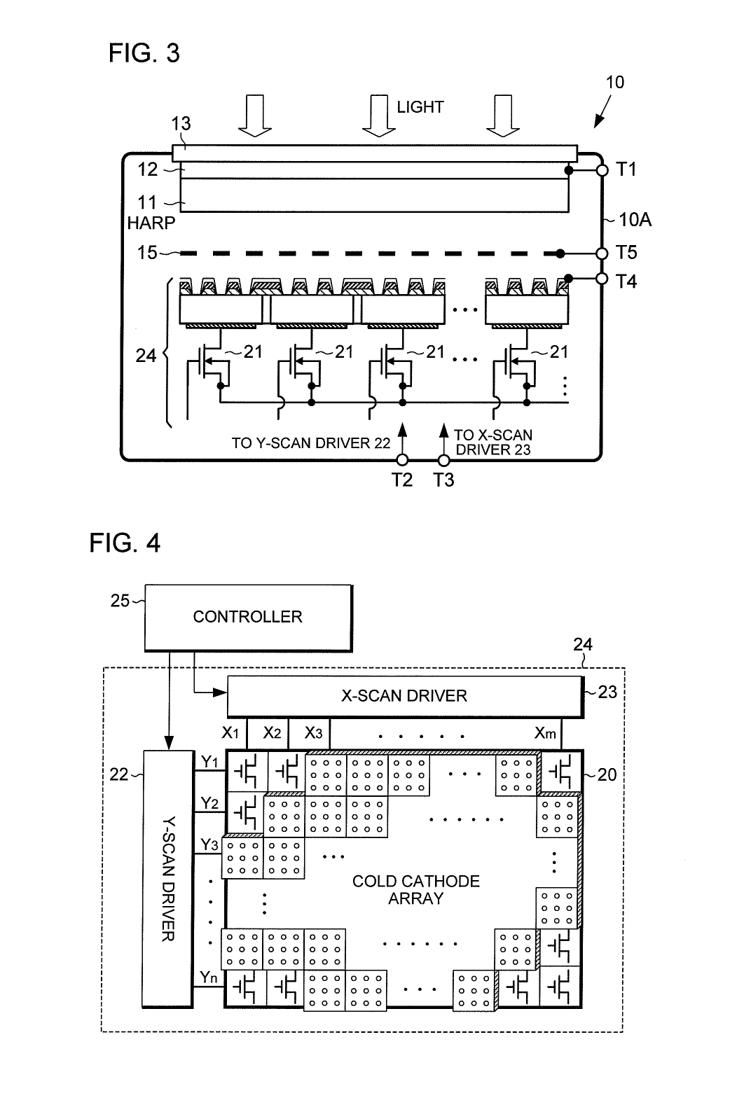

FIG. 3 is a cross-sectional view showing schematically the configuration of a HEED cold cathode HARP sensing device 10. The HEED cold cathode HARP sensing device (hereinafter, also referred to as a cold cathode sensing device) 10 is an image sensing device comprising a combination of an active drive HEED (High-efficiency Electron Emission Device) cold cathode array and a HARP (High-gain Avalanche Rushing amorphous Photoconductor) photoelectric conversion film. More specifically, the cold cathode sensing device 10 has a HARP photoelectric conversion film 11, a HEED cold cathode array chip 24, a mesh electrode (or intermediate electrode) 15 placed between the HARP photoelectric conversion film 11 and a HEED cold cathode array 20. As described later, in the HEED cold cathode array chip 24, the active drive HEED cold cathode array (hereinafter simply referred to as a HEED cold cathode array) 20, and a Y-scan driver 22 and an X-scan driver 23 (not shown) are integrally formed. Although the case where a photoelectric conversion film of the HARP structure is used as the photoelectric conversion film and where a cold cathode array of the HEED structure is used as the cold cathode array will be described, these are illustrative only, and a photoelectric conversion film of and a cold cathode array or electron supplying source of other structures may be used.

As shown in the figure, the HARP photoelectric conversion film 11 is formed on a transparent or light-transmissive conductive film 12, and the transparent conductive film 12 is formed on a transparent substrate 13. The HARP photoelectric conversion film 11 is made mainly of amorphous selenium (Se), but another material, for example, silicon (Si) or a compound semiconductor such as lead oxide (PbO), cadmium selenide (CdSe), or gallium arsenide (GaAs) can be used. The transparent conductive film 12 can be formed of a tin oxide (SnO₂) film, an ITO (indium tin oxide) film, or the like. A predetermined positive voltage (hereinafter also called a HARP potential or HARP voltage) is applied to the transparent conductive film 12 via a connection terminal (i.e., input/output terminal) T1 provided on a glass housing 10A as described later.

The transparent substrate 13 need only be formed of material transmitting light with wavelengths that the cold cathode sensing device 10 senses. For example, where capturing or image sensing with visible light is performed, the transparent substrate 13 is formed of material such as glass transmitting visible light, and where capturing with ultraviolet light is performed, it is formed of material such as sapphire or quartz glass transmitting ultraviolet light. Where capturing with X-rays is performed, it need only be formed of material transmitting X-rays such as beryllium (Be), silicon (Si), boron nitride (BN), aluminum oxide (Al₂O₃), or the like.

The mesh electrode 15 is provided with multiple openings and is formed of a widely known metal material, alloy, semiconductor material, or the like. A predetermined positive voltage (hereinafter, also referred to as a mesh voltage or mesh potential) is applied to the mesh electrode 15 via a connection terminal T5. The mesh electrode is an intermediate electrode provided for electron acceleration and excess electron retrieval.

As to the HEED cold cathode array 20, although described in detail later, the gate electrodes of the MOS (Metal Oxide Semiconductor) transistors for driving the HEED are connected to the X-scan driver 23 (or a horizontal scan circuit), and the source electrodes (S) thereof are connected to the Y-scan driver 22 (or a vertical scan circuit) so as to perform dot sequential scanning. The Y-scan driver 22 and the X-scan driver 23 are integrally formed together with the HEED cold cathode array 20 as one chip in the HEED cold cathode array chip 24, which is provided in the glass housing 10A (not shown). The signals and voltage necessary to drive the HEED cold cathode array chip 24 are supplied via connection terminals (input/output terminals) T2, T3, T4 provided on the glass housing 10A.

All these constituents are vacuum encapsulated in the glass housing 10A sealed with frit glass or indium metal.

FIG. 4 is a block diagram showing the configuration of the HEED cold cathode array 20, the Y-scan driver 22 and the X-scan driver 23 for driving the HEED cold cathode array 20, and a controller 25 for controlling the entire apparatus. The Y-scan driver 22 and the X-scan driver 23 are integrally formed as one chip into the HEED cold cathode array chip 24. The controller 25 and other circuits described later may be provided on this chip.

The HEED cold cathode array 20, as schematically shown in FIG. 4, is constituted by an active drive field emitter array (FEA) in which the HEED cold cathode array is laid directly on, and integrated with, a drive circuit LSI formed on a Si wafer, and can deal with high-speed drive (the drive pulse width for one pixel is, e.g., no greater than several tens ns) for the image capturing operation that involves dot sequential scanning. The HEED cold cathode array 20 comprises multiple pixels arranged in a matrix with “n” rows and “m” columns (the number of pixels is n×m) which are respectively connected to “n” number of scan drive lines arranged in the Y-direction (vertical direction) and “m” number of scan drive lines (hereinafter simply called scan lines) arranged in the X-direction (horizontal direction). For example, it is constituted as a high-definition HEED cold cathode array of 640×480 pixels (VGA standard). According to, for example, the NTSC standard, the frame rate is 30 frames per second, and for image sensor apparatuses having 640×480 pixels (VGA standard), the length of the pixel period is usually about several tens ns (nanoseconds), for example, 80 ns.

The Y-scan driver 22 and the X-scan driver 23 perform dot sequential scanning and pixel driving based on control signals such as a vertical synchronizing signal (V-Sync), a horizontal synchronizing signal (H-Sync), and a clock signal (CLK) from the controller 25. In other words, the dot sequential scanning is performed as follows: the scan lines (Yj, j=1, 2, . . . , n) are sequentially scanned in the Y-direction, during which while one scan line (here Yk) is selected, the scan lines (Xi, i=1, 2, . . . , m) are sequentially scanned in the X-direction, thereby selecting and driving each pixel on the scan line (Yk).

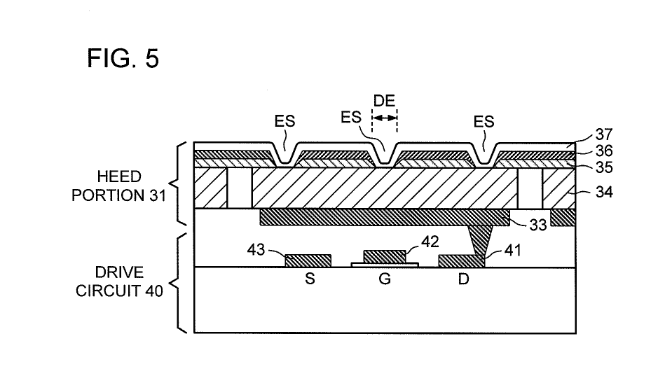

FIG. 5 is a diagram for illustrating the structure of the active drive HEED cold cathode array 20, which is a partial cross-sectional view schematically showing a pixel portion on an enlarged scale. After a drive circuit 40 comprising a MOS transistor array and the Y-scan driver 22 and the X-scan driver 23 to drive and control the drive circuit 40 are formed, a HEED portion 31 is formed on top of the drive circuit 40 to form the HEED cold cathode array 20.

As shown in FIG. 5, the HEED portion 31 is a cold cathode electron emission source of an MIS (Metal Insulator Semiconductor) type having a stacked structure of a lower electrode 33, a silicon (Si) layer 34, a silicon oxide (SiOx) layer 35, an upper electrode 36 made of, e.g., tungsten (W), and a carbon (C) layer 37. While the upper electrode 36 of the HEED cold cathode array 20 is common to all the pixels, each pixel is electrically isolated by dividing the lower electrode 33 and the Si layer 34.

The lower electrode 33 of the HEED portion 31 is connected to the drain electrode D of a MOS transistor of the drive circuit 40 via a via hole. As described above, the gate electrode G and the source electrode S of the MOS transistor are connected to the X-scan driver 23 and the Y-scan driver 22. The switching for making each pixel emit electrons is performed by controlling the drain potential of its MOS transistor, that is, the potential of the lower electrode 33 of the pixel in the HEED portion 31.

The number of pixels of the HEED cold cathode array 20 is, for example, 640×480 pixels (VGA), and the size of one pixel is 20×20 μm². Emission sites ES that are openings for electron emission are formed in the surface of each pixel. For example, 3×3 of emission sites ES (1 μmφ) having a diameter DE of about 1 μm are formed in an area of 8×8 μm² of a pixel. An electron flow of, e.g., several microamperes (μA) is emitted from one emission site ES (emission current density: about 4 A/cm²). Note that numerical values shown in this embodiment are illustrative only, and that they can be changed for use as needed depending on the apparatus where the image sensing device is used, the resolution and sensitivity of the image sensing device, and the like.

### [Configuration and Operation of the Image Sensor Apparatus]

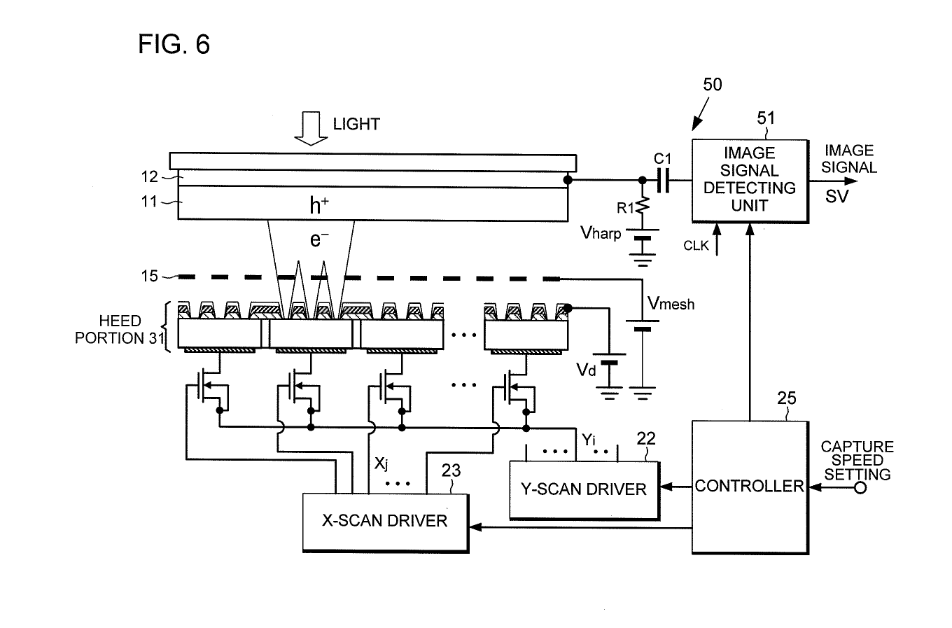

FIG. 6 is a diagram showing schematically the configuration of the image sensor apparatus 50 of this embodiment. The image sensor apparatus 50 is provided with an image signal detecting unit 51, the Y-scan driver 22, the X-scan driver 23, and the controller 25 for controlling the image signal detecting unit 51.

As shown in FIG. 6, the apparatus is configured such that with the transparent conductive film 12 being connected to an external power supply circuit, a predetermined positive voltage (HARP voltage) Vharp is applied to the HARP photoelectric conversion film 11, and that a HARP current is supplied to the image signal detecting unit 51 via a capacitor C1. Further, the apparatus is configured such that a predetermined positive voltage Vmesh (mesh voltage or MESH voltage) is applied to the mesh electrode 15, and that a predetermined positive voltage Vd (HEED drive voltage) is applied to the upper electrode 36 of the HEED portion 31. These voltages are set, for example, as follows: Vharp=1.5 kV, Vmesh=470 V, Vd=23 V, but are not limited to these values.

Next, the operation of the image sensor apparatus 50 will be described. When external light is incident on the HARP photoelectric conversion film 11 through the transparent conductive film 12, a corresponding number of electron-hole pairs to the incident light amount are generated in part of the inside of the film near the transparent conductive film 12. The holes of the pairs are accelerated by a strong electric field applied to the HARP photoelectric conversion film 11 via the transparent conductive film 12, and collide one after another with atoms forming part of the HARP photoelectric conversion film 11 to generate new electron-hole pairs. Holes avalanche-multiplied in this way are accumulated at the side of the HARP photoelectric conversion film 11 facing the HEED cold cathode array 20 (the side opposite to the transparent conductive film 12), and thus a pattern of holes corresponding to an incident light image is formed. The current occurring when the pattern of holes combines with electrons emitted from the HEED cold cathode array 20 is output as a HARP current signal corresponding to the incident light image.

A setting value for an image capturing speed is input into the controller 25, and the controller 25 generates control signals including an image-capturing-speed specifying signal based on the capturing speed setting value and supplies them to the Y-scan driver 22, the X-scan driver 23, and the image signal detecting unit 51.

Each of the constituents of the image sensor apparatus 50 including the Y-scan driver 22, the X-scan driver 23, the image signal detecting unit 51, and the controller 25 operates based on (or synchronously with) the clock signal (CLK) to perform various operations such as the control of each constituent, the detection of various signals, driver driving, and signal processing, which are described herein.

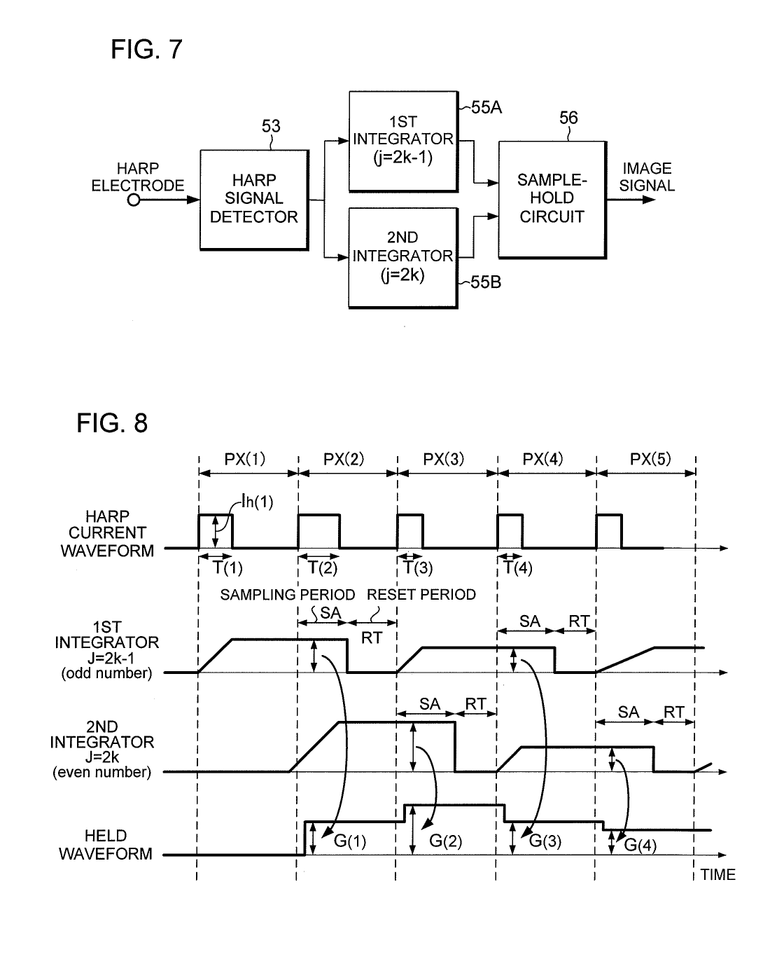

FIG. 7 is a block diagram showing the configuration of the image signal detecting unit 51 that is Embodiment 1. The image signal detecting unit 51 comprises a HARP signal detector 53, a first integrator 55A, a second integrator 55B, and a sample-hold circuit 56. As described above, these constituents of the image signal detecting unit 51 operate based on the clock signal (CLK) under the control of the controller 25.

FIG. 8 shows schematically the output signal waveform of each constituent of the image signal detecting unit 51 for first to fifth pixels PX(j) (j=1 to 5), for easiness of understanding and convenience of description. Additionally, the pixel period for these pixels is denoted as PX(j), using the same symbol for description.

The HARP signal detector 53 is connected to the capacitor C1 provided for the HARP photoelectric conversion film 11 and detects the HARP current signal for each pixel based on the clock signal (CLK). FIG. 8 shows operation in the case where the amounts of emitted electrons from the elements of the HEED cold cathode array corresponding to the pixels PX(j) are the same. In other words, the HARP electric current values (pulse heights) Ih(j) for the pixels PX(j) (j=1 to 5) are all equal, and the duration of the HARP current (neutralization current) T(j), hereinafter referred to as the HARP current duration, differs according to the amount of incident light on the pixel area PX(j). For example, in the case shown in the figure, the incident light amount for PX(2) is greater than the incident light amount for PX(1), and as to the HARP current duration, T(1)<T(2).

As shown in FIGS. 7 and 8, the first integrator 55A performs integration of the HARP current with regard to odd ordinal numbered pixel periods PX(j)=PX(2k−1), where k is a natural number. The second integrator 55B performs integration of the HARP current for even ordinal numbered pixel periods PX(j)=PX(2k). That is, the first integrator 55A and the second integrator 55B alternately perform temporal integration or time-integration over the pixel period.

The first integrator 55A and the second integrator 55B can be comprised of, e.g., an operational amplifier, or alternatively a circuit performing current sink or drawing and capacitor charging, or the like.

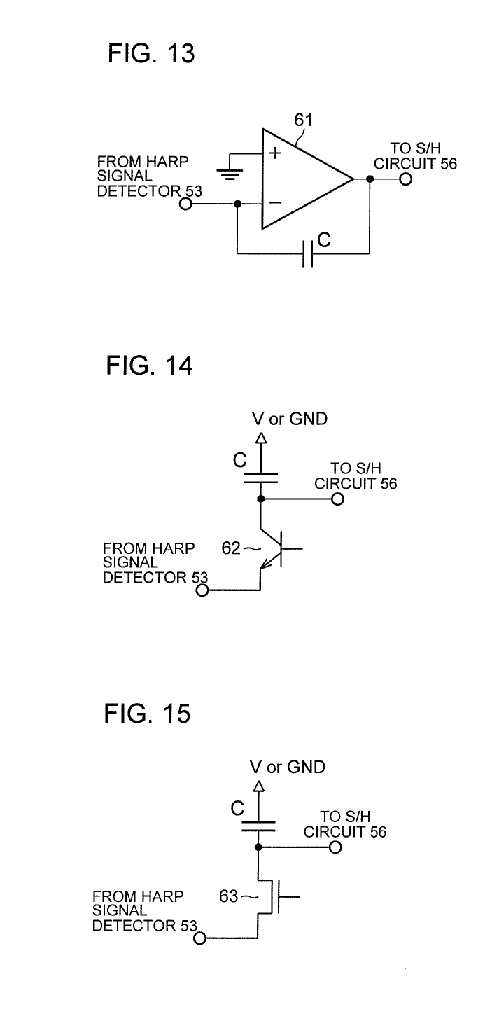

FIG. 13 is a circuit diagram showing an example of the circuit configuration of the first integrator 55A and the second integrator 55B. Specifically, the first integrator 55A comprises an operational amplifier 61 and a capacitor C. The non-inverting input (+) of the operational amplifier 61 is connected to ground (GND), and the inverting input (−) and the output thereof are connected via the capacitor C. Further, the output of the operational amplifier 61 is connected to the sample-hold (S/H) circuit 56. The inverting input (−) of the operational amplifier 61 is connected to the HARP signal detector 53, which supplies the HARP current signal thereto. Thus, the HARP current signal from the HARP signal detector 53 is integrated by the first integrator 55A, and the integral value is supplied to the sample-hold circuit 56. A resistor may be provided on the input side of the operational amplifier 61, that is, in series between the inverting input (−) and the HARP signal detector 53.

Note that a reset circuit (not shown) for discharging charges from the capacitor C is provided in the first integrator 55A. Also, the second integrator 55B has the same configuration.

As mentioned above, the constituents of the image signal detecting unit 51 including the first integrator 55A and the second integrator 55B operate under the control of the controller 25. The integral values of the integrators are reset at predetermined timings by the control of the controller 25 as described in detail later.

FIGS. 14 and 15 show other examples of the first integrator 55A and the second integrator 55B. FIG. 14 shows an emitter-sink type integrator using a bipolar transistor 62 and a capacitor C. That is, the emitter of the bipolar transistor 62 is supplied with the HARP current signal from the HARP signal detector 53. Its collector connected to one terminal of the capacitor C is connected to the sample-hold circuit 56, and the integral value of the HARP current signal is supplied to the sample-hold circuit 56. The other terminal of the capacitor C is connected to a power supply (voltage V) or ground (GND).

FIG. 15 shows a source-sink type integrator using a field effect transistor (FET) 63 and a capacitor C. That is, the source of the FET 63 is supplied with the HARP current signal from the HARP signal detector 53. Its drain connected to the capacitor C is connected to the sample-hold circuit 56, and the integral value of the HARP current signal is supplied to the sample-hold circuit 56.

The configuration of the first integrator 55A and the second integrator 55B is not limited to these. They need only be configured to perform integration of the HARP current signal and output the integral value.

To be more specific, as shown in FIG. 8, the first integrator 55A performs integration of the HARP current for an odd ordinal numbered pixel period PX(1). The sample-hold circuit 56 samples the integral waveform of the HARP current during the even ordinal numbered pixel period PX(2) subsequent to that odd ordinal numbered pixel period (sampling period SA) and holds the sampled value. After the sampling finishes, the first integrator 55A (its integral value) is reset during the subsequent pixel period PX(2) (reset period RT). The resetting of the integrator is performed by the control of the controller 25 functioning as reset means. The reset means continues to reset the first integrator 55A until the beginning of the next odd ordinal numbered pixel period PX(3), which is the next integration pixel period for the first integrator 55A, and controls integration to start at the beginning of the pixel period PX(3). Note that the reset means need only be formed such that the resetting being performed after the sampling finishes, temporal integration is started anew at the beginning of the next integration pixel period for the first integrator 55A.

Likewise, as shown in FIG. 8, the second integrator 55B performs integration of the HARP current for an even ordinal numbered pixel period PX(2). The sample-hold circuit 56 samples the integral waveform of the HARP current during the odd ordinal numbered pixel period PX(3) subsequent to the even ordinal numbered pixel period (sampling period) and holds the sampled value. After the sampling finishes, the integral value is reset during the subsequent pixel period PX(3) by the control of the controller 25. Then, the controller 25 controls the second integrator 55B to start integration at the beginning of the next even ordinal numbered pixel period PX(4). For the pixel periods PX(3), PX(4), . . . , the same integration and sample-hold operation are performed. The sample-hold circuit 56 outputs the sampled values G(1), G(2), G(3), G(4), . . . of the above-described integral signals as an image signal SV (FIG. 8). Thus, the image signal detecting unit 51 can generate an accurate image signal corresponding to the amounts of incident light on the pixel areas of the HARP photoelectric conversion film 11.

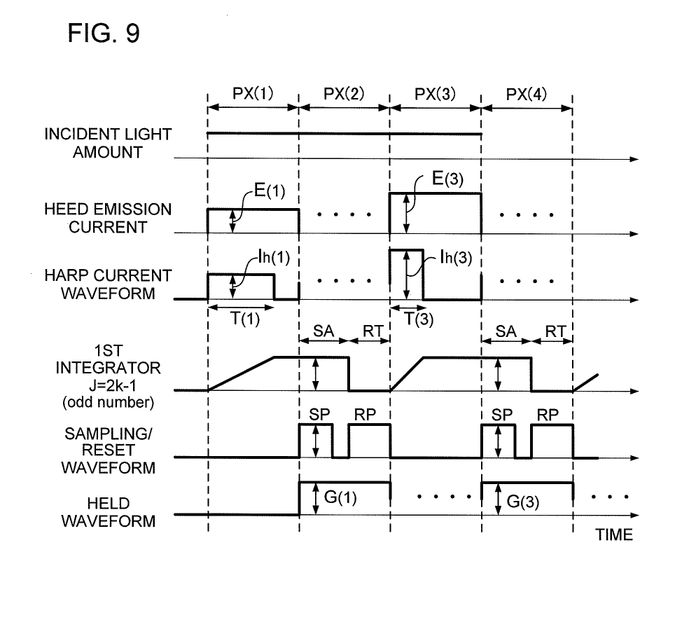

FIG. 9 shows the operation of the first integrator 55A in the case where the amounts of incident light on the pixel areas of the HARP photoelectric conversion film 11 are the same and where the amounts of emitted electrons from the elements of the HEED cold cathode array 20 are different. Of the odd ordinal numbered pixel periods PX(1), PX(3), PX(5), . . . , only pixel periods PX(1), PX(3) are shown for easiness of understanding and convenience of description. That is, FIG. 9 shows the operation of the first integrator 55A in the case where the HEED emitted electron amount (emission current) E(1)<E(3). In this case, as to the HARP electric current value (pulse height), Ih(1)<Ih(3), but as to the HARP current period, T(1)>T(3).

The first integrator 55A performs integration of the HARP current for the odd ordinal numbered pixel periods PX(1), PX(3). After the neutralization of holes accumulated in each pixel area finishes, the integral value of the HARP current is the same, i.e., Ih(1)×T(1)=Ih(3)×T(3). In other words, after the period T(1), T(3) has elapsed, their integral value becomes the same value G(1)=G(3) corresponding to the incident light amount.

The sample-hold circuit 56 samples the integral waveform of the HARP current during predetermined sampling period SA in the pixel period PX(2), PX(4) subsequent to the odd ordinal numbered pixel period PX(1), PX(3) (sampling pulse SP) and holds the sampled value. After the sampling finishes, the integral value is reset during the subsequent pixel period PX(2), PX(4) (reset pulse RP).

In other words, after the integration finishes so that the waveform becomes constant, the sampling is performed. That is, because the sampling is performed after the neutralization by emitted electrons of holes accumulated in each pixel area finishes, an accurate integral value (or pixel value) G(k) corresponding to the incident light amount can be obtained even where the amount of emitted electrons (i.e., the HARP current period) from each element of the HEED cold cathode array is different. Then, the sample-hold circuit 56 holds the pixel value G(k) (k=1, 3, 5, . . . ).

The integration and sample-hold operation by the second integrator 55B and the sample-hold circuit 56 for the even ordinal numbered pixel periods PX(2), PX(4), PX(6), . . . are performed in the same manner.

The case where the amounts of incident light on the pixel areas are the same and where the amounts of emitted electrons are different has been described with reference to FIG. 9. As can be seen from the above description, also in the case where the amounts of incident light on the pixel areas are different and where the amounts of emitted electrons from the elements of the HEED cold cathode array 20 are different, an accurate integral value corresponding to the incident light amount can be obtained without noise due to variation in the amount of emitted electrons, likewise.

Thus, even in the case where the amounts of emitted electrons (i.e., the HARP current periods) from the HEED cold cathode array elements are different, the image signal detecting unit 51 can generate an accurate image signal corresponding to the amounts of incident light on the pixel areas of the HARP photoelectric conversion film 11. Further, because the integrators 55 are used, noise due to variation in the amount of emitted electrons does not occur.

Moreover, according to the present invention, because the apparatus is configured such that with a plurality of integrators provided, the integrators sequentially perform integration for the respective corresponding pixel periods, there can be provided an image sensor apparatus that is capable of high image quality capturing with high S/N even if the pixel periods are made shorter than in the conventional art. In other words, by shortening the pixel periods (e.g., by half), the number of frames per second can be made greater (e.g., twice), and thus an image sensor apparatus capable of high image quality capturing and high-speed capturing (or slow motion capturing) with high S/N can be provided. Alternatively, by shortening the pixel periods (e.g., by half), a high-definition image sensor apparatus capable of higher-resolution (e.g., twice) high S/N capturing can be provided.

### Embodiment 2

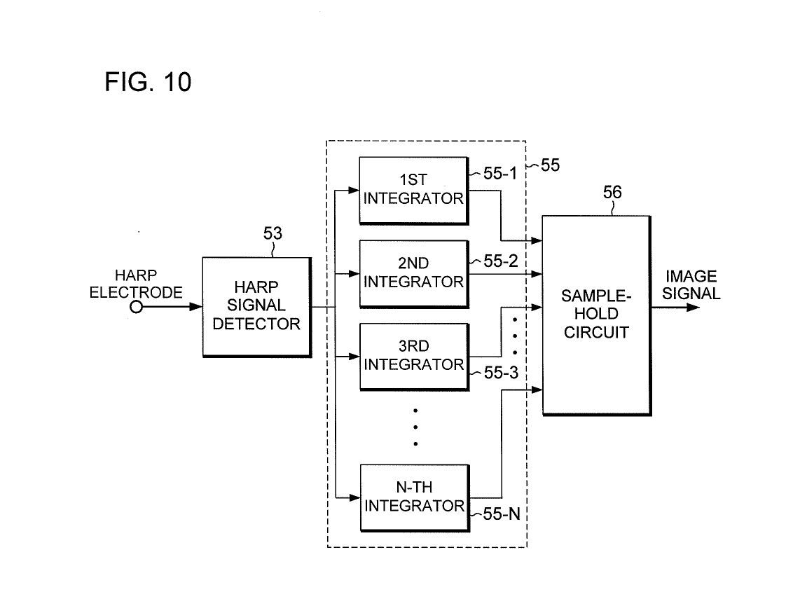

FIG. 10 is a block diagram showing the configuration of the image signal detecting unit 51 according to Embodiment 2 of the present invention. The image signal detecting unit 51 comprises a HARP signal detector 53, first, second, . . . , N'th integrators 55-1, 55-2, . . . , 55-N, and a sample-hold circuit 56. In the above-described Embodiment 1, the case where the first integrator 55A and the second integrator 55B performs integration respectively for the odd ordinal numbered and even ordinal numbered pixel periods are provided has been described. In contrast, in this embodiment, N number of integrators (N is an integer of 3 or greater) are provided. For each of the first, second, . . . , N'th integrators 55-1, 55-2, . . . , 55-N, an integration circuit using an operational amplifier, an integration circuit using current sink and capacitor charging, or so on can be used as in the above Embodiment 1. Further, as described above, these constituents of the image signal detecting unit 51 operate based on the clock signal (CLK) under the control of the controller 25.

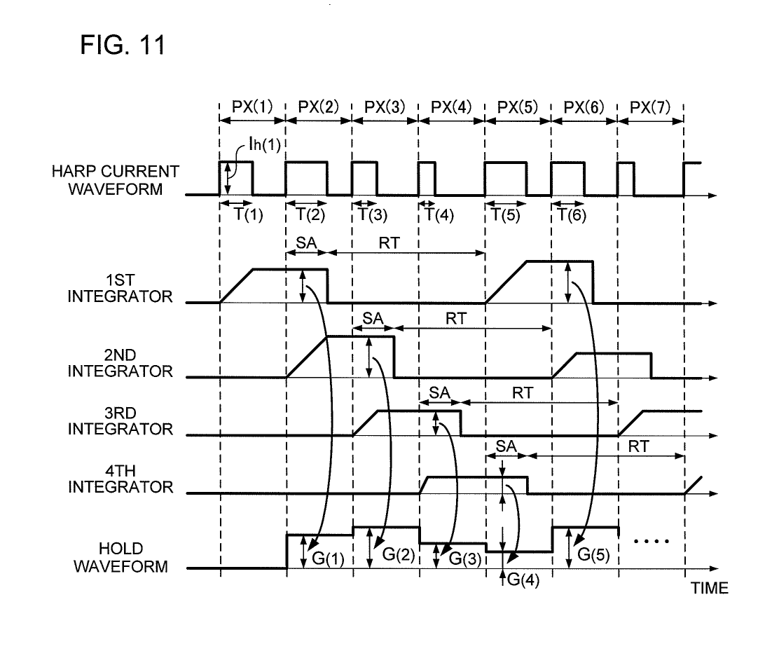

FIG. 11 shows schematically the output signal waveform of each constituent of the image signal detecting unit 51. For easiness of understanding and convenience of description, description will be made taking as an example the case where the image signal detecting unit 51 comprises four integrators (N=4), that is, the first to fourth integrators 55-1 to 55-4 and for the first to seventh pixels PX(j) (j=1 to 7).

The first to fourth integrators 55-1 to 55-4 performs integration of the HARP current for the pixel periods PX(4k−3), PX(4k−2), PX(4k−1), PX(4k) (“k” is a natural number) respectively. More specifically, the first integrator 55-1 performs integration of the HARP current for the pixel periods PX(1), PX(5), PX(9), . . . . First, the first integrator 55-1 produces an integral waveform for the pixel period PX(1) (referred to as a first integral waveform). The sample-hold circuit 56 samples the integral waveform of the HARP current during the pixel period PX(2) subsequent to that pixel period PX(1) (sampling period SA) and holds the sampled value (G(1)). After the sampling finishes, the integral value is reset during the subsequent pixel period PX(2) (reset period RT).

The resetting of the integrator is performed by the control of the controller 25 functioning as reset means. The reset means resets the first integrator 55-1 so that the integration starts at the beginning of the pixel period PX(5) that is the next integration pixel period for the first integrator 55-1.

The second integrator 55-2 performs integration of the HARP current for the pixel period PX(2). The sample-hold circuit 56 samples the integral waveform of the HARP current during the pixel period PX(3) subsequent to that pixel period PX(2) and holds the sampled value (G(2)). The resetting of the second integrator 55-2 (integral waveform) by the reset means is the same as in the case of the first integrator 55-1 described above, and the second integrator 55-2 is reset so that the integration by the second integrator 55-2 starts at the beginning of the pixel period PX(6) that is the next integration pixel period for the second integrator 55-2.

Likewise, the third integrator 55-3 and the fourth integrator 55-4 performs integration of the HARP current for the pixel periods PX(3), PX(4). Then, the third and fourth integral waveforms are sampled by the sample-hold circuit 56 during the pixel periods PX(4), PX(5) subsequent to those, and the sampled values G(3), G(4) are obtained. The integration and the sampling-hold operation are repeated, and thus a signal consisting of the sampled values G(1), G(2), G(3), G(4), . . . is output as an image signal SV from the sample-hold circuit 56 (FIG. 11).

Thus, with this configuration, because the apparatus is configured such that three or more integrators sequentially perform integration for the respective corresponding pixel periods, the pixel periods can be made further shorter than in the previously-described embodiment. More specifically, the pixel periods can be made further shorter, and the number of frames per second can be made greater, and an image sensor apparatus capable of high-speed capturing (or slow-motion capturing) with high S/N can be provided. Alternatively, by shortening the pixel periods, a high-definition image sensor apparatus capable of high-resolution and high S/N capturing can be provided. As described above, this embodiment can be applied to image sensor apparatuses of further higher definition than Embodiment 1.

### Embodiment 3

The present invention can be applied to a variable-speed, high-speed image capturing mode where capturing speed is variable. The configuration of the image signal detecting unit 51 is the same as in Embodiment 2. In this embodiment, the controller 25 controls the Y-scan driver 22, the X-scan driver 23, and the image signal detecting unit 51 based on a sensing speed setting.

To be more specific, when the image capturing speed setting is at a double-speed capturing mode, the controller 25 designates two of the first to N'th integrators 55-1 to 55-N (e.g., the first and second integrators 55-1, 55-2) and controls them to operate in the same way as in Embodiment 1. In this case, the controller 25 controls the Y-scan driver 22 and the X-scan driver 23 so that the length of the pixel period PX(j) is, for example, half of that for when capturing in a normal capturing mode (i.e., single speed) is performed. In addition, the controller 25 specifies the timings for the integration of the two integrators, i.e., the first and second integrators 55-1, 55-2 and for the sampling-and-hold operation of the sample-hold circuit 56. When being at a quadruple-speed capturing mode, for example, the first to fourth integrators 55-1 to 55-4 are designated, and the similar integration and sampling-and-hold operation are performed, and the image signal SV is output.

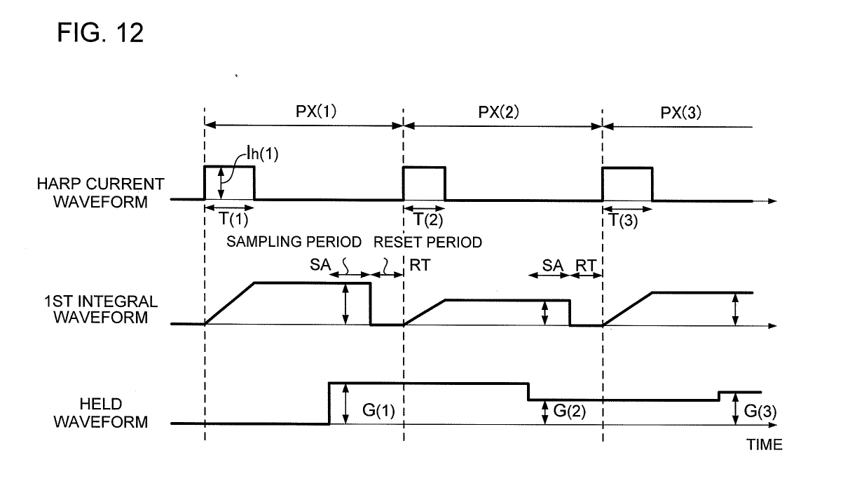

FIG. 12 shows schematically the output signal waveform of each constituent of the image signal detecting unit 51 for the case where the normal capturing mode (i.e., single-speed) capturing is performed. That is, when the capturing speed setting is at the normal capturing mode (single speed), the controller 25 designates one integrator (e.g., the first integrator 55-1) and controls the Y-scan driver 22, the X-scan driver 23, and each constituent of the image signal detecting unit 51. For easiness of understanding and convenience of description, the waveforms are shown for the first to third pixels PX(1) to PX(3).

The first integrator 55-1 that is the above-described one integrator performs integration of the HARP current for the pixel periods PX(j) (j is a natural number). After the integral waveform becomes constant in each of the pixel periods PX(j), that is, after the neutralization of holes accumulated in each pixel area finishes, the sample-hold circuit 56 samples the integral waveform of the HARP current (sampling period SA) and then holds the sampled value. After the sampling finishes, the controller 25 functioning as reset means resets the first integrator 55-1 so that the integration starts at the beginning of the pixel period PX(j+1) subsequent to that pixel period.

Also in this case, even if the amounts of emitted electrons (i.e., the HARP current periods) from the HEED cold cathode array elements are different, the image signal detecting unit 51 can generate an accurate image signal corresponding to the amounts of incident light on the pixel areas of the HARP photoelectric conversion film 11. Further, because the integrators are used, noise due to variation in the amount of emitted electrons does not occur. Thus, high image-quality capturing with high S/N is possible.

As such, generally in a similar manner, capturing in a K-multiple speed capturing mode (K=1, 2, 3, . . . , N) can be performed. That is, according to the embodiment, also for the variable-speed capturing mode, a high-definition high-speed image sensor apparatus can be provided as with the above embodiments. Further, even if there is variation in the amount of emitted electrons, noise does not occur in the image signal, and hence an image signal of high image quality which has a high signal-to-noise ratio (S/N) in principle can be generated.

Note that the above embodiments can be applied in combination as needed. Further, although in the above embodiments description has been made taking as an example the case where a HEED cold cathode array is used as the cold cathode array and a HARP photoelectric conversion film is used as the photoelectric conversion film, the present invention can be applied to image sensor apparatuses using various cold cathode arrays, electron supplying sources, and photoelectric conversion films. The materials, numerical values, and so on shown in the above embodiments are illustrative only.

1. An image sensor apparatus which includes a photoelectric conversion film generating holes due to light incidence; an electron supplying source array having a plurality of electron supplying sources arranged in a matrix; and a scan driver that scans said electron supplying source array to supply electrons sequentially to a plurality of pixel areas of said photoelectric conversion film, said image sensor apparatus comprising:
a photoelectric-conversion-film current detector which detects a photoelectric conversion film current produced by combination of the holes generated in said photoelectric conversion film with electrons supplied from said electron supplying source array to said photoelectric conversion film;
a plurality of integrators which sequentially perform temporal integration on said photoelectric conversion film current during respective corresponding pixel periods during which electrons are supplied to said pixel areas, so as to generate integral signals;
a sampling portion which samples the integral signals of said plurality of integrators in each of said pixel periods to generate an image signal; and
a controller which, according to an image capturing speed setting, determines said pixel periods and selects integrators to sequentially perform temporal integration on said photoelectric conversion film current from among said plurality of integrators and which controls said scan driver, said selected integrators and said sampling portion according to said image capturing speed setting.

2. An image sensor apparatus according to claim 1, comprising a reset portion which, for each of selected integrators after the sampling of said integral signal finishes, continues to reset the selected integrators until the beginning of the next pixel period during which the selected integrators performs temporal integration.

3. An image sensor apparatus according to claim 1, wherein said reset portion resets each of the selected integrators in the pixel period subsequent to each of pixel periods during which the selected integrators perform temporal integration.

4. An image sensor apparatus according to claim 1, wherein the selected integrators are two integrators which alternately perform temporal integration for said pixel period.

5. (canceled)
